(19) United States
(12) Patent Application Publication
(10) Pub. No.: US 2014/0063980 A1
(43) Pub. Date: Mar. 6, 2014

(54) SEMICONDUCTOR MEMORY DEVICE AND OPERATING METHOD THEREOF

(71) Applicant: SK HYNIX INC, Gyeonggi-do (KR)

(72) Inventors: Byoung-Kwan JEONG, Gyeonggi-do (KR); Jee-Yul KIM, Gyeonggi-do (KR)

(73) Assignee: SK HYNIX INC., Gyeonggi-do (KR)

(21) Appl. No.: 13/719,397

(22) Filed: Dec. 19, 2012

(30) Foreign Application Priority Data
Aug. 29, 2012 (KR) 10-2012-0095052

(51) Int. Cl. G11C 7/00

(52) U.S. Cl. CPC G11C 7/00
USPC 365/189.09

(57) ABSTRACT

An operation method of a semiconductor memory device includes forming a first data distribution by performing a first programming operation during a first write operation, outputting a predetermined data by detecting the first data distribution on the basis of a first reference voltage corresponding to the first programming operation during a first read operation, forming a second data distribution by performing a second programming operation during a second write operation, and outputting data that is the same as the predetermined data corresponding to the first data distribution during the first read operation by detecting the second data distribution on the basis of a second reference voltage corresponding to the second programming operation during a second read operation.

### CROSS-REFERENCE TO RELATED APPLICATION

The present application claims priority of Korean Patent application No. 10-2012-0095052, filed on Aug. 29, 2012, which is incorporated herein by reference in its entirety.

### BACKGROUND

1. Field

Exemplary embodiments of the present invention relate to a semiconductor design technology, and, more particularly, a semiconductor memory device and an operating method thereof for forming a plurality of data distributions and performing a read operation and a write operation.

2. Description of the Related Art

In general, a semiconductor memory device is classified into a volatile memory device including a dynamic random access memory (DRAM) and a non-volatile memory device including a programmable read only memory (PROM), an erasable PROM (EPROM), an electrically EPROM (EEPROM), a flash memory device and the like depending on the preservation of data stored in a memory cell after a predetermined time.

In other words, the data stored in a memory cell of the volatile memory device is not preserved after a predetermined time, but the data stored in a memory cell of the non-volatile memory device is preserved after a predetermined time. Thus, it may be desired for the volatile memory device, instead of the non-volatile memory device, to perform a refresh operation to preserve data. Because of this feature of the non-volatile memory device, the non-volatile memory device is widely used in a portable storage device.

A flash memory of the non-volatile memory device stores data in a memory cell by performing a programming operation and an erase operation. The programming operation represents an operation for charging an electron on a floating gate of a transistor included in a memory cell. The erase operation represents an operation for discharging the electron charged on the floating gate of the transistor to a substrate.

The flash memory device stores data of ‘1’ or ‘0’ on the memory cell by performing the programming operation or the erase operation. During a read operation, the flash memory device detects an amount of the electron charged on the floating gate and determines whether the data stored in the memory cell is data with the value of ‘1’ or data with the value of ‘0’ based on a detected result.

FIG. 1 is a data distribution diagram illustrating an operation method of a conventional flash memory device.

An erase data distribution and a programming data distribution in the conventional flash memory device are shown in FIG. 1. The erase data distribution corresponding to data with the value of ‘1’ is formed by performing an erase operation. The programming data distribution corresponding to data with the value of ‘0’ is formed by performing a programming operation.

During a write operation, the flash memory device forms the erase data distribution or the programming data distribution according to the data with the value of ‘1’ or ‘0’ during a write operation. During a read operation, the flash memory device detects the erase data distribution or the programming data distribution according to a reference voltage VR, and then outputs the data with the value of ‘1’ or ‘0’. Forming a data distribution corresponding to the data having the value of ‘1’ or ‘0’ indicates the storing of the data. Detecting a formed data distribution represents outputting the data corresponding to the formed data distribution.

The flash memory device performs a programming operation with a page unit and an erase operation with a memory block unit due to structural reasons of the flash memory. In order to store the data having the value of ‘0’ in a memory cell, to read the stored data, and to store the data with the value of ‘1’, first, the erase operation should be performed in all memory cells of a memory block, including a corresponding memory cell. Next, a page including the corresponding memory cell is activated, and the data with the value of ‘1’ is stored in the corresponding memory cell of the page. Then, the data that is stored in the other memory cells of the page is stored with the same value again, and data that is stored in memory cells of the other pages should be stored with the same value again.

As described above, even if the data of one memory cell is changed, the conventional flash memory device may perform the read operation and the write operation ineffectively due to structural malfunctions of the conventional flash memory device

### SUMMARY

Exemplary embodiments of the present invention are directed to a semiconductor memory device and an operation method for consecutively performing a read operation and a write operation without an erase operation.

In accordance with an exemplary embodiment of the present invention, an operation method of a semiconductor memory device includes forming a first data distribution by performing a first programming operation during a first write operation, outputting a predetermined data by detecting the first data distribution on the basis of a first reference voltage corresponding to the first programming operation during a first read operation, forming a second data distribution by performing a second programming operation during a second write operation, and outputting data that is the same as the predetermined data corresponding to the first data distribution during the first read operation by detecting the second data distribution on the basis of a second reference voltage corresponding to the second programming operation during a second read operation.

In accordance with another exemplary embodiment of the present invention, an operation method of a semiconductor memory device includes forming a plurality of data distributions on a plurality of memory cells by performing a programming operation, detecting the plurality of data distributions on the basis of a predetermined reference voltage, setting an Nth data distribution of the plurality of data distributions as a first data distribution corresponding to an erase state and an N+1th data distribution of the plurality of data distributions as a second data distribution corresponding to a programming state, forming the first data distribution by programming a memory cell to be erased out of the plurality of memory cells, forming the second data distribution by programming a memory cell to be programmed out of the plurality of memory cells, and detecting the plurality of data distributions formed on the plurality of memory cells in response to a reference voltage corresponding to the first data distribution and the second distribution.

In accordance with still another exemplary embodiment of the present invention, an operation method of a semiconductor memory device includes forming at least two data distributions on a plurality of memory cells by performing a programming operation, detecting the at least two data distributions on the basis of a reference voltage, setting one of at least two data distributions as a temporary erase data distribution corresponding to an erase state, forming the temporary erase data distribution by performing a programming operation on a memory cell to be erased out of the plurality of memory cells, performing a programming operation on a memory cell to be programmed out of the plurality of memory cells, and detecting a data distribution formed on the plurality of memory cells in response to the reference voltage corresponding to the programming operation.

### BRIEF DESCRIPTION OF THE DRAWINGS

FIG. 1 is a data distribution diagram illustrating an operation method of a conventional flash memory device.

FIG. 2 is a flow chart illustrating an operation method of a semiconductor memory device in accordance with a first embodiment of the present application.

FIG. 3 is a data distribution diagram illustrating an operation method of a semiconductor device shown in FIG. 2.

FIG. 4 is a flow chart illustrating an operation method of a semiconductor memory device in accordance with a second embodiment of the present application.

FIG. 5 is a data distribution diagram illustrating an operation method of a semiconductor device shown in FIG. 4.

FIG. 6 is a flow chart illustrating an operation method of a semiconductor memory device in accordance with a third embodiment of the present application.

FIG. 7 is a data distribution diagram illustrating an operation method of a semiconductor device shown in FIG. 6.

FIG. 8 is a flow chart illustrating an operation method of a semiconductor memory device in accordance with a fourth embodiment of the present application.

FIG. 9 is a block diagram illustrating a semiconductor memory device in accordance with an embodiment of the present application.

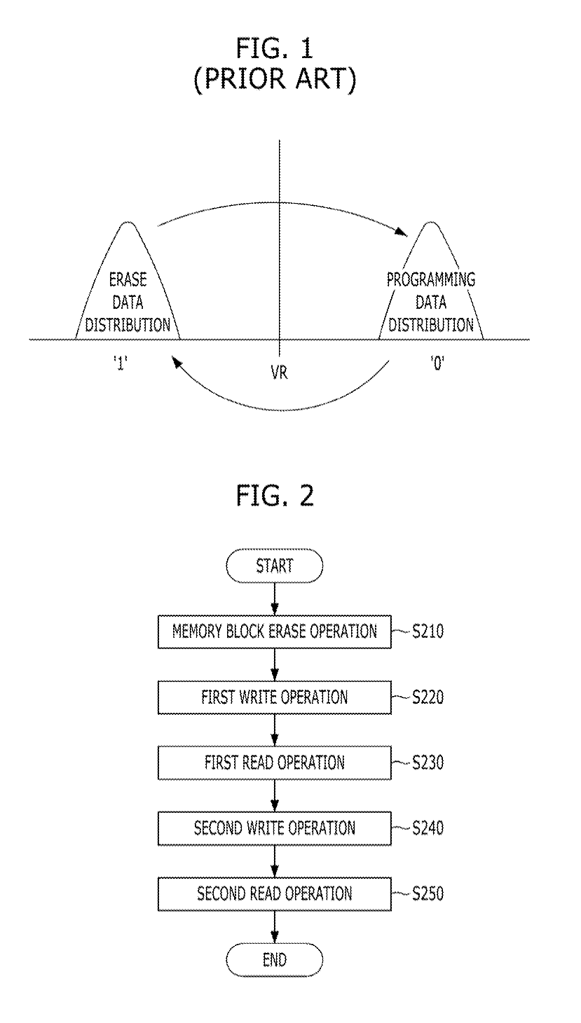

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete and will fully convey the scope of the present invention to those skilled in the art. Throughout the disclosure, reference numerals correspond directly to the like numbered parts in the various figures and embodiments of the present invention.

FIG. 2 is a flow chart illustrating an operation method of a semiconductor memory device in accordance with a first embodiment of the present application.

Referring to FIG. 2, an operation method of a semiconductor memory device includes performing an erase operation in a memory block at step S210, performing a first write operation at step S220, performing a first read operation at step S230, performing a second write operation at step S240 and performing a second read operation at step S250.

The operation method of a semiconductor memory device in accordance with a first embodiment of the present application may consecutively perform a write operation and a read operation without an erase operation. In other words, after the first read operation at step S230, the second write operation is performed without the erase operation at step S240. This increases a speed of data processing operation. The operation method of the semiconductor memory device will be described below in detail.

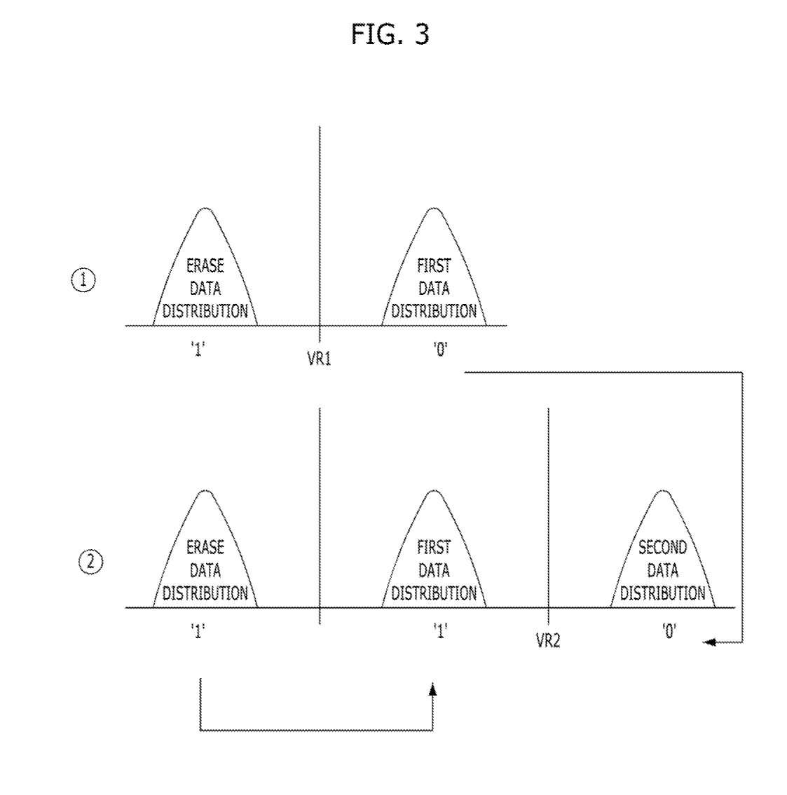

FIG. 3 is a data distribution diagram illustrating an operation method of a semiconductor device shown in FIG. 2.

For the convenience of the description, the data distribution that is formed by the erase operation is defined as a data distribution with a value of ‘1’.

Referring to FIGS. 2 and 3, at the step S210, the erase operation is performed in a memory block before the write operation.

In other words, an erase data distribution is formed in all memory cells of the memory block.

At the step S220, a first data distribution of \textcircled{1} shown in FIG. 3 is formed by performing a first programming operation according to a first write operation. In other words, an erase data distribution and the first data distribution are formed such as \textcircled{1} shown in FIG. 3 according to the data to be stored in a plurality of memory cells.

At the step S230, a first read operation is performed, and the data distribution is detected on the basis of a first reference voltage VR1. The first read operation is completed by outputting the erase data distribution as the data with the value of ‘1’ and the first data distribution as the data with the value of ‘0’.

At the step S240, a second data distribution of \textcircled{2} shown in FIG. 3 is formed by performing a second programming operation according to a second write operation. In other words, the erase data distribution, the first data distribution and the second data distribution are further formed such as \textcircled{2} shown in FIG. 3 according to the data to be stored in the plurality of memory cells. The second data distribution is formed by performing a programming operation on the erase data distribution or on the first data distribution.

At the step S250, the second data distribution is detected on the basis of a second reference voltage VR2 by performing a second read operation. The second read operation is completed by outputting the erase data distribution as the data with the value of ‘1’, the first data distribution as the data with the value of ‘1’ and the second data distribution as the data with the value of ‘0’.

In other words, data distribution is detected on the basis of the first reference voltage VR1 corresponding to the programming operation for forming the first data distribution at \textcircled{1}. Thus, the first data distribution corresponding to the data with the value of ‘0’ at \textcircled{1} corresponds to the data with the value of ‘1’ at \textcircled{2} corresponding to the second read operation. Such correspondence indicates that the data with the value of ‘0’ is stored in a memory cell and reads the data stored in the memory cell, and then the data having the value of ‘1’ is stored only by the programming operation without the erase operation.

In accordance with a first embodiment of the present application, after the semiconductor memory device, reads the data stored in a corresponding memory cell, the semiconductor memory device may store new data on the corresponding memory cell by performing only the programming operation without the erase operation, indicating that a processing speed of the data is increased in proportion to the amount of time performing the erase operation.

The write operation is performed twice after the step S210 in FIG. 2. However, the semiconductor memory device, in accordance with a first embodiment of the present application, may perform a consecutive write operation and a consecutive read operation more than two times.

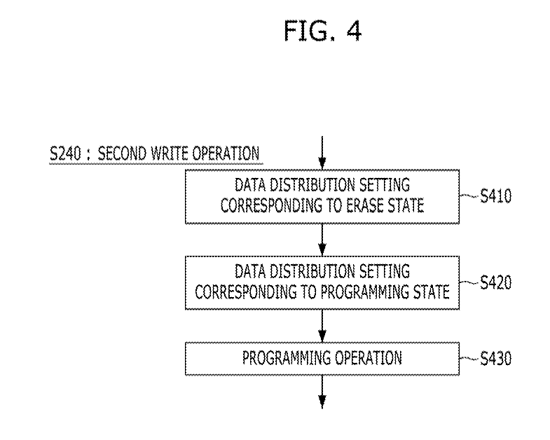

One data may correspond to a plurality of data distributions in FIG. 3. For example, a data distribution corresponding to the data with the value of ‘1’ may be the erase data distribution and the first data distribution. However, if the data distribution is formed in such a manner as shown in FIG. 3, the data distribution (e.g., the second data distribution of ‘2’) to be formed by a next programming operation may be far away from a data distribution (e.g., the erase data distribution of ‘1’) to be programmed. Thus, a time to be used in a next programming operation may be extended. Interference may lower reliability of a memory cell. Accordingly, during a write operation, an operation method shown in FIG. 4 may be used to prevent problems described above.

FIG. 4 is a flow chart illustrating an operation method of a semiconductor memory device in accordance with a second embodiment of the present application.

For the convenience of the descriptions, it is assumed that at least two data distributions are formed in a plurality of memory cells before the second write operation at step S240 shown in FIG. 2.

Referring to FIG. 4, the second write operation at step S240 of the operation method of the semiconductor memory device includes setting a data distribution corresponding to an erase state at step S410 (hereinafter, referred to as “temporary erase data distribution”), setting a data distribution corresponding to a programming state at step S420 (hereinafter, referred to as “programming data distribution”), and performing a programming operation at step S430.

The operation method of a semiconductor memory device in accordance with the second embodiment of the present application relates to a case of forming at least two data distributions. During a read operation, the plurality of data distributions are detected on the basis of a predetermined reference voltage, and then a write operation is performed without an erase operation. During the write operation, the temporary erase data distribution and the programming data distribution are formed in the plurality of memory cells, which reduces a consumed time and the influence of the interference during a programming operation.

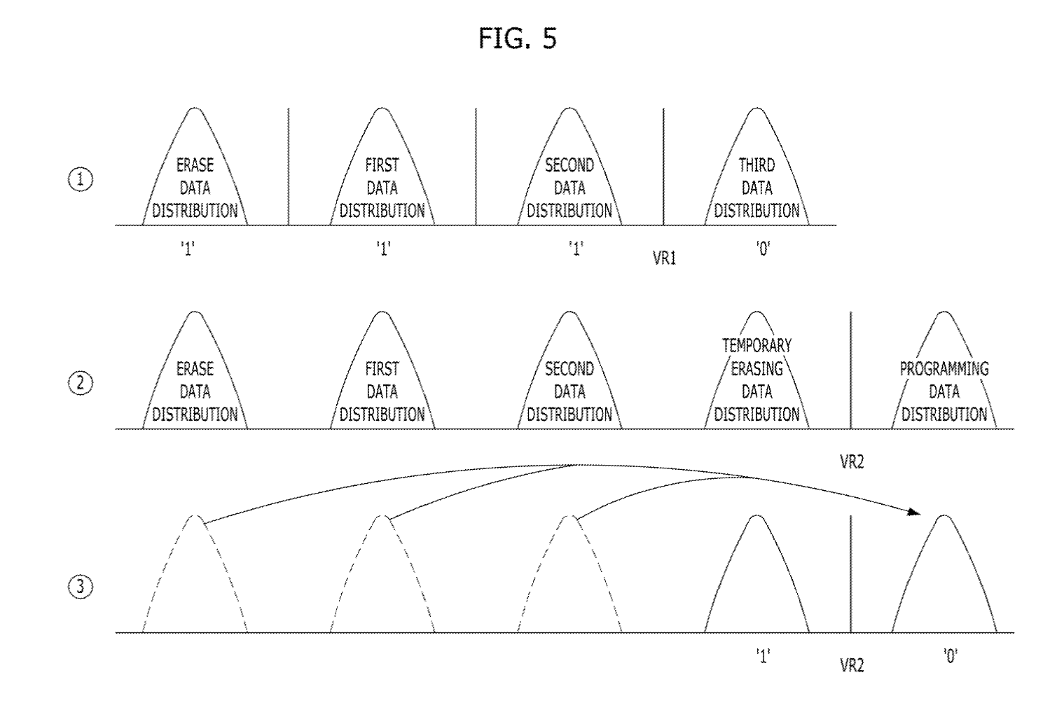

FIG. 5 is a data distribution diagram illustrating an operation method of a semiconductor device shown in FIG. 4. For the convenience of the descriptions, the data distributions are formed in case of the plurality of write operations as shown in \textcircled{1} of FIG. 5.

At the step S410, the third data distribution as a last data distribution from first to third data distributions may set as the temporary erase data distribution as shown in \textcircled{2} of FIG. 5. At the step S420, the data distribution to be formed by the programming operation may set as the programming data distribution as shown in \textcircled{2} of FIG. 5.

At the step S430, the programming operation is performed. As shown in \textcircled{3} of FIG. 5, the erase data distribution, the first data distribution and the second data distribution are formed as the temporary erase data distribution or the programming data distribution according to data to be stored. The temporary erase data distribution is output as the data with the value of ‘1’, and the programming data distribution is output as the data with the value of ‘0’ according to the second reference voltage VR2.

In accordance with a second embodiment of the present application, in the semiconductor memory device, the programming operation is performed by setting the last data distribution as the temporary data distribution and a next distribution as the programming data distribution during the write operation after read operation. Thus, the temporary erase data distribution or the programming data distribution is formed in each of all the memory cells of the semiconductor memory device.

Therefore, a distance between the data distribution to be programmed and the data distribution to be formed during the next programming operation is minimized. This reduces the influence of the interference and a consumed time during the next programming operation.

At the step S430, a region that forms the temporary erase data distribution may be overlapped with a region that forms the programming data distribution. After the temporary erase data distribution is formed, the programming data distribution may be formed according to a design.

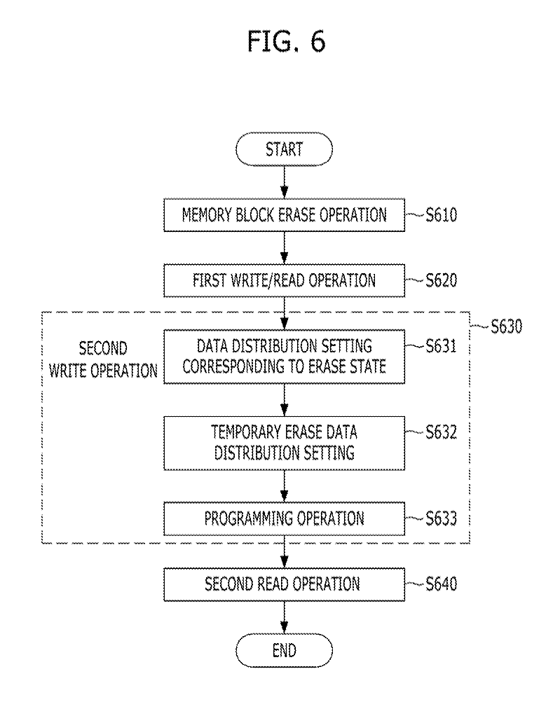

FIG. 6 is a flow chart illustrating an operation method of a semiconductor memory device in accordance with a third embodiment of the present application. The third embodiment of the present application is described in case that a memory cell has a multi-level cell structure.

Referring to FIG. 6, in accordance with a third embodiment of the present application, an operation method of a semiconductor memory device includes performing an erase operation on a memory block at step S610, performing a first write operation and a first read operation at step S620, performing a second write operation at step S630, and performing a second read operation. The step S630 of the performing the second write operation includes setting a data distribution corresponding to an erase state at step S631 (hereinafter, referring to ‘temporary erase data distribution’), forming the temporary erase data distribution at step 632, and performing the programming operation at step S633.

The operation method of the semiconductor memory device in accordance with a third embodiment of the present application relates to a case of forming at least two data distribution during the first write operation. The semiconductor memory device detects a plurality of data distributions on the basis of a predetermined reference voltage during the first write operation and performs a write operation without an erase operation.

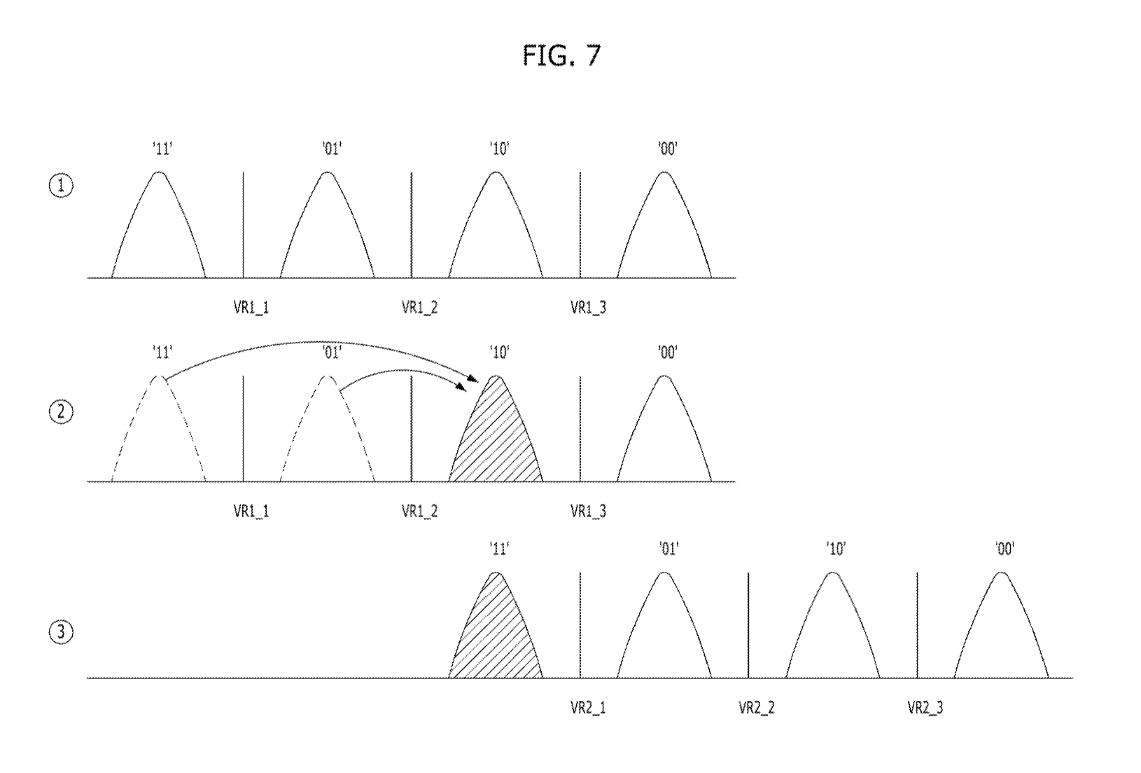

FIG. 7 is a data distribution diagram illustrating an operation method of a semiconductor device shown in FIG. 6.

For the convenience of the descriptions, a multi-level cell structure having two bits is exemplarily described. In a case of the multi-level cell structure having two bits, four data may be stored. Moreover, a data distribution that is formed by the erase operation is defined as a data distribution having the value of ‘11’.

Referring to FIGS. 6 and 7, an erase operation is performed in a memory block before a write operation at step S610. In other words, all memory cell of the memory block form an erase data distribution.

As shown in \textcircled{1} of FIG. 7, a plurality of data distributions is formed by performing a programming operation according to a first write operation at step S620. In other words, a data distribution with the value of ‘11’ as an erase data distribution, a data distribution with the value of ‘01’ as a programming data distribution, a data distribution with the value of ‘10’ and a data distribution with the value of ‘00’ are formed according to data to be stored in a plurality of memory cells.

At the step S620, the plurality of data distributions are detected on the basis of first to third reference voltages VR1_1, VR1_2 and VR1_3 shown in \textcircled{1} of FIG. 7 by performing a first read operation. The first read operation is completed by outputting the data distribution with the value of ‘11’ as data with the value of ‘11’, outputting the data distribution with the value of ‘01’ as data with the value of ‘01’, outputting the data distribution with the value of ‘10’ as data with the value of ‘10’ and outputting the data distribution with the value of ‘00’ as data with the value of ‘00’.

The step S630 for performing the second write operation includes setting a data distribution corresponding to an erase state at a step S631, forming a temporary erase data distribution at a step S632 and performing a programming operation at a step S633.

One of the data distributions with the value of ‘01’ the data distribution with the value of ‘10’ and the data distribution with the value of ‘00’ is set as the temporary erase data distribution. The temporary data distribution is the data distribution corresponding to the erase state. As shown in \textcircled{2} of FIG. 2, the data distribution with the value of ‘10’ is defined as the temporary erase data distribution.

At the step S632, the temporary erase data distribution is formed by performing a programming operation on a memory cell that is to be erased of the plurality of memory cells. In other words, the data distribution with the value of ‘10’ as the temporary erase data distribution is formed by performing the programming operation on the memory cell that is to be erased of the memory cells comprising of the data distribution with the value of ‘11’ and the data distribution with the value of ‘01’.

At the step S633, the data distribution shown in \textcircled{3} of FIG. 7 is formed by performing the programming operation on the memory cell that is to be programmed of the plurality of memory cells. In other words, as shown in \textcircled{3} of FIG. 7 the data distribution with the value of ‘11’, the data distribution with the value of ‘01’, the data distribution with the value of ‘10’, and the data distribution with the value of ‘00’ are formed according to data to be stored in a plurality of memory cells.

The data distribution with the value of ‘01’, the data distribution with the value of ‘10’ and the data distribution with the value of ‘00’ correspond to the data distribution shown in FIG. 5. The number of the programming data distributions corresponds to the number of data that is indicated. In FIG. 7, the number of data is four including the values of ‘11’, ‘10’, ‘01’ and ‘00’, and four data distributions including the temporary erase data distribution. The programming data distribution is formed.

At the step S640, the plurality of data distributions is detected on the basis of the first to third reference voltages VR2_1, VR2_2 and VR2_3 by performing the second read operation. The second read operation is completed by outputting the data distribution with the value of ‘11’ as the data with the value of ‘11’, outputting the data distribution with the value of ‘01’ as the data with the value of ‘01’, outputting the data distribution with the value of ‘10’ as the data with the value of ‘10’, and outputting the data distribution with the value of ‘00’ as the data with the value of ‘00’.

The semiconductor memory device containing the multi-level cell structure in accordance with the third embodiment of the present application stores new data by performing only the programming operation after reading the data stored in the memory cell of the semiconductor memory device.

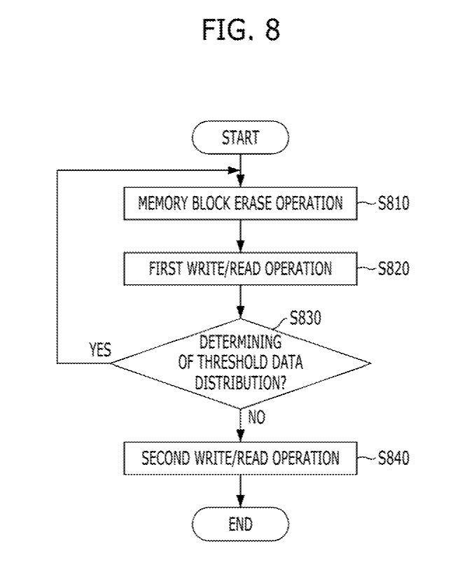

As shown in FIG. 3, FIG. 5 and FIG. 7, the data distribution is shifted rightward. This represents that the threshold voltage of the memory cell is increased. But, realistically, it is impossible to unlimitedly increase the threshold voltage of the memory cell. Thus, an operation method of the semiconductor memory device shown in FIG. 8 is requested to limit the threshold voltage of the memory cell.

FIG. 8 is a flow chart illustrating an operation method of a semiconductor memory device in accordance with a fourth embodiment of the present application.

Referring to FIG. 8, in accordance with a fourth embodiment of the present application, an operation method of a semiconductor memory device includes performing an erase operation on a memory block at step S810, performing a first write operation and a first read operation at step S820, determining a threshold data distribution at step S830 and performing a second write operation and a second read operation at step S840.

At the step S810, the erase operation is performed on the memory block before a write operation.

At the step S820, a data distribution is formed by performing a programming operation according to the first write operation. The formed data distribution is detected by performing the first read operation.

The step S830 determines whether the data distribution formed at the step S820 is a threshold data distribution. The threshold data distribution may vary according to a design, and may represent the data distribution that cannot perform the programming operation any more.

If the data distribution formed at the step S820 is the threshold data distribution, the erase operation is performed on the memory block at the step S810. On the other hand, if the data distribution formed at the step S820 is not the threshold data distribution, the second write operation and the second read operation are performed at the step S840.

In accordance with a fourth embodiment of the present application, the semiconductor memory device determines the performance of the erase operation on the memory block by determining whether the data distribution formed by performing consecutive programming operations is the threshold data distribution. Thus, the number of performances of erase operations on the memory block may be minimized.

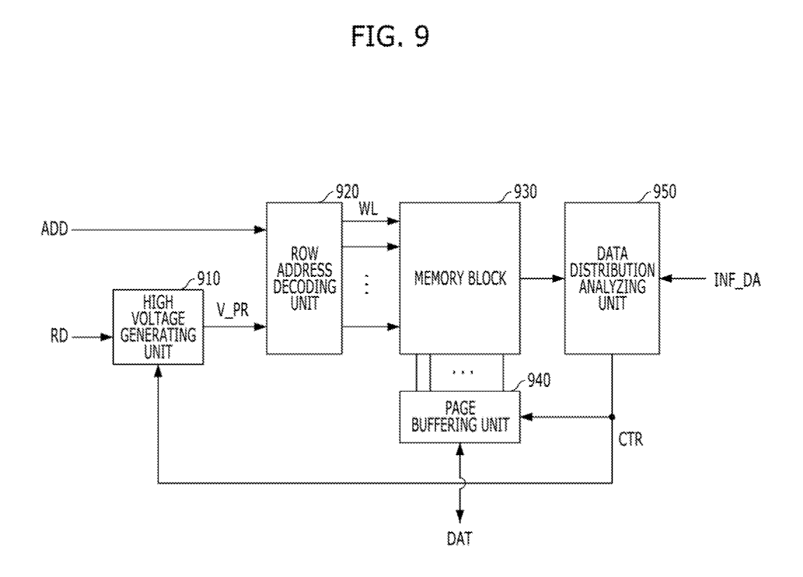

FIG. 9 is a block diagram illustrating a semiconductor memory device in accordance with an embodiment of the present application.

Referring to FIG. 9, the semiconductor memory device includes a high voltage generating unit 910, a row address decoding unit 920, a memory block 930, a page buffering unit 940 and a data distribution analyzing unit 950.

The high voltage generating unit 910 generates a programming voltage V_PR in response to a read command RD. A voltage level of the programming voltage V_PR is controlled in response to a control signal CTR generated from the data distribution analyzing unit 950.

The row address decoding unit 920 decodes an address AD and activates a corresponding word line WL. An activated word line WL has a voltage level corresponding to the programming voltage V_PR.

A data distribution is formed on the memory block 930 according to the voltage level of the activated word line WL, which is, the voltage level of the programming voltage V_PR and the programming operation corresponding to the data to be stored.

The page buffering unit 940 is coupled to the memory block 930 and controls an input operation and an output operation of the data. The page buffering unit 940 detects the data distribution formed on the memory block in response to a reference voltage during a read operation.

The data distribution analyzing unit 950 analyzes the data distribution formed on the memory block 930 and generates the control signal CTR. The control signal CT has information that determines an adjustment of the programming voltage V_PR and the reference voltage, e.g., VR1 and VR2 of FIG. 3. The reference voltage is used on the basis of detecting the data during the read operation, and the programming voltage V_PR is used on the basis of forming the data distribution during the write operation.

Meanwhile, the data distribution analyzing unit 950 may be designed variously. In FIG. 9, the data distribution analyzing unit 950 compares the data distribution of the memory block 930 with data information INF_DAT to be stored consecutively and generates the control signal CTR based on a compared result.

For example, if the data distribution of the memory block 930 is the same as the data information INF_DAT to be stored consecutively, it is not requested to adjust the programming voltage V_PR and the reference voltage. If only the first data distribution shown in \textcircled{2} of FIG. 3 is programmed by the erase data distribution shown in \textcircled{1} of FIG. 3, it is not requested to adjust the programming voltage V_PR and the reference voltage. Thus, the data distribution analyzing unit 950 generates the control signal CTR that does not adjust the reference voltage and the programming voltage V_PR.

Further, the data distribution analyzing unit 950 controls the high voltage generating unit 910 and the page buffering unit 940 under the circumstances of FIG. 8. In other words, the data distribution analyzing unit 950 controls the high voltage generating unit 910 to generate the programming voltage V_PR in order to perform an erase operation on the memory block and controls the page buffering unit 940 to perform the detecting operation of the data.

As described above, in accordance with an embodiment of the present application, the semiconductor memory device may perform the write operation and the read operation consecutively without the erase operation and may increase the operation speed of the data processing. A consumed time and the influence of the interference may be reduced during a next programming operation by minimizing a distance between the data distribution to be programmed and the data distribution to be formed during the next programming operation.

While the present invention has been described with respect to the specific embodiments, it will be apparent to those skilled in the art that various changes and modifications may be made without departing from the spirit and scope of the invention as defined in the following claims.

What is claimed is:

1. An operation method of a semiconductor memory device, comprising:
forming a first data distribution by performing a first programming operation during a first write operation;
outputting a predetermined data by detecting the first data distribution on the basis of a first reference voltage corresponding to the first programming operation during a first read operation;
forming a second data distribution by performing a second programming operation during a second write operation; and
outputting data that is the same as the predetermined data corresponding to the first data distribution during the first read operation, by detecting the second data distribution on the basis of a second reference voltage corresponding to the second programming operation during a second read operation.

2. The operation method of claim 1, further comprising:
performing an erase operation on a memory block including a plurality of memory cells before the forming of the first data distribution.

3. The operation method of claim 1, wherein the outputting of the data that is the same as the predetermined data outputs different data from the predetermined data by detecting the first data distribution of the basis of the second reference voltage.

4. The operation method of claim 3, wherein the different data has a data value corresponding to a data distribution of an erase state.

5. The operation method of claim 1, further comprising:
comparing a threshold data distribution with the first data distribution formed by the first programming operation or the second data distribution formed by the second programming operation; and
performing an erase operation on the memory block including a plurality of memory cells based on the compared results.

6. An operation method of a semiconductor memory device, comprising:
forming a plurality of data distributions on a plurality of memory cells by performing a programming operation;
detecting the plurality of data distributions on the basis of a predetermined reference voltage;
setting an Nth data distribution of the plurality of data distributions as a first data distribution corresponding to an erase state, and an N+1th data distribution of the plurality of data distributions as a second data distribution corresponding to a programming state;
forming the first data distribution by program ring a memory cell to be erased out of the plurality of memory cells;
forming the second data distribution by programming a memory cell to be programmed out of the plurality of memory cells; and
detecting the first data distribution formed on the plurality of memory cells in response to a reference voltage corresponding to the first data distribution and the second distribution formed on the plurality of memory cells in response to a reference voltage corresponding to the second data distribution.

7. The operation method of claim 6, further comprising: performing an erase operation on a memory block including the plurality of memory cells before the forming of the plurality of data distributions.

8. The operation method of claim 6, wherein the forming of the second data distribution is performed after the forming of the first data distribution is completed.

9. The operation method of claim 6, further comprising:
comparing a threshold data distribution with the second data distribution; and
performing an erase operation on a memory block including the plurality of memory cells based on the compared result.

10. The operation method of claim 6, the number of the first data distribution or the number of the second data distribution correspond to the number of data that is represented.

11. An operation method of a semiconductor memory device, comprising:
forming at least two data distributions on a plurality of memory cells by performing a first programming operation;
detecting the at least two data distributions on the basis of a predetermined reference voltage;
setting one of at least two data distributions as a temporary erase data distribution corresponding to an erase state;
forming the temporary erase data distribution by performing a second programming operation on a memory cell to be erased out of the plurality of memory cells;
performing a third programming operation on a memory cell to be programmed out of the plurality of memory cells; and
detecting a data distribution formed on the plurality of memory cells in response to a reference voltage corresponding to the third programming operation.

12. The operation method of claim 11, further comprising: forming an erase data distribution of an erase state by performing an erase operation on a memory block including the plurality of memory cells before the forming of the at least two data distributions.

13. The operation method of claim 12, wherein the temporary erase data distribution is different from the erase data distribution.

14. The operation method of claim 11, further comprising:
comparing the temporary erase data distribution with a threshold data distribution; and
performing an erase operation on a memory block including the plurality of memory cells based on the compared result.

15. The operation method of claim 11, wherein the number of the data distribution formed by the performing of the third programming operation or the number of the temporary data distribution correspond to the number of data that is represented.

16. A semiconductor memory device, comprising:
a high voltage generating unit configured to generate a programming voltage in response to a read command;
a row address decoding unit configured to decode an address and activate a corresponding word line to the programming voltage;
a memory block configured to form a data distribution thereon according to a programming operation corresponding to data and a voltage level of the word line;
a page buffering unit configured to control an input operation and an output operation of the data, and detect the data distribution formed on the memory block in response to a reference voltage during a read operation; and
a data distribution analyzing unit configured to analyze the data distribution formed on the memory block and generates the control signal,
wherein the programming voltage and the reference voltage are controlled in response to the control signal.

17. The semiconductor memory device of claim 16, wherein the data distribution analyzing unit compares the data distribution of the memory block with data information to be stored consecutively and generates the control signal based on a compared result.

18. The semiconductor memory device of claim 16, wherein the programming voltage and the reference voltage include a predetermined voltage, respectively, and if the data distribution formed on the memory block is a threshold data distribution, each of the programming voltage and the reference voltage is set to the predetermined voltage.
